(19) United States
(12) Patent Application Publication
(10) Pub. No.: US 2010/0118621 A1
(43) Pub. Date: May 13, 2010

(54) Implementing Variation Tolerant Memory Array Signal Timing

(75) Inventors: Chad Allen Adams, Byron, MN (US); Derick Gardner Behrends, Rochester, MN (US); Travis Reynold Hebig, Rochester, MN (US)

Correspondence Address: IBM CORPORATION;ROCHESTER IP LAW DEPT 917, 3605 HIGHWAY 52 N, ROCHESTER, MN, 55901-7829, US

(73) Assignee: INTERNATIONAL BUSINESS MACHINES CORPORATION, Armonk, NY (US)

(21) Appl. No.: 12/266,580

(22) Filed: Nov. 7, 2008

(51) Int. Cl. G11C 7/00

(52) U.S. Cl. 365/189.08; 365/191; 365/194

(57) ABSTRACT

A method and signal timing adjustment circuit for implementing variation tolerant memory array signal timing, and a design structure on which the subject circuit resides are provided. A logic circuit generates a first delay signal based upon logic devices forming the logic circuit. A memory cell circuit receives the first delay signal and generates control signals responsive to the first delay signal and based upon memory cell devices forming the memory cell circuit. A programmable logic delay circuit receives the control signals and generates a timing adjustment signal.

### FIELD OF THE INVENTION

The present invention relates generally to the data processing field, and more particularly, relates to a method and circuit for implementing variation tolerant memory array signal timing, and a design structure on which the subject circuit resides.

### DESCRIPTION OF THE RELATED ART

In advanced CMOS technologies it is becoming common practice for static random access memory (SRAM) cells to have unique voltage threshold (Vt) implants independent from other standard logic devices. This causes SRAM cell variation to be independent of logic device variation.

As a result, process variation can cause logic devices to speed up while SRAM cells slow down or vice versa. This is a problem in sensitive SRAM array circuits where timing on certain signals is critical to the operation of the design.

For example, the wordline pulse width is tuned according to the performance of the SRAM cell, but in current methodology logic devices determine wordline pulse width. Other sensitive signals that are tuned according to the performance of the SRAM cell are the sense amplifier set signal in sense amplifier designs and the global precharge signal in domino designs. In current methodology, logic devices determine the timing of both of these signals.

A need exists for an effective mechanism for implementing variation tolerant memory array signal timing.

### SUMMARY OF THE INVENTION

Principal aspects of the present invention are to provide a method and circuit for implementing variation tolerant memory array signal timing, and a design structure on which the subject circuit resides. Other important aspects of the present invention are to provide such method, circuit, and design structure substantially without negative effect and that overcome many of the disadvantages of prior art arrangements.

In brief, a method and circuit for implementing variation tolerant memory array signal timing, and a design structure on which the subject circuit resides are provided. A logic circuit generates a first delay signal based upon logic devices forming the logic circuit. A memory cell circuit receives the first delay signal and generates control signals responsive to the first delay signal and based upon memory cell devices forming the memory cell circuit. A programmable logic delay circuit receives the control signals and generates a timing adjustment signal.

In accordance with features of the invention, the logic circuit generates the first delay signal includes a logic device pulse generator. The logic device pulse generator generates an output pulse having a width dependent upon a delay of the logic devices forming the logic device pulse generator circuit.

In accordance with features of the invention, the memory cell circuit receives the first delay signal and generates control signals includes a static random access memory (SRAM) oscillator and a plurality of latches connected to the SRAM oscillator. A respective latch is coupled to each respective stage of the SRAM oscillator. An output of the latches provides the control signals responsive to the first delay signal and based upon memory cell devices forming the memory cell circuit.

In accordance with features of the invention, the programmable logic delay circuit is formed of logic devices that are programmable by the control signals.

### BRIEF DESCRIPTION OF THE DRAWINGS

The present invention together with the above and other objects and advantages may best be understood from the following detailed description of the preferred embodiments of the invention illustrated in the drawings, wherein:

FIG. 1 is a schematic diagram illustrating an example signal timing adjustment circuit for implementing variation tolerant memory array signal timing in accordance with the preferred embodiment; and

FIG. 2 is a flow diagram of a design process used in semiconductor design, manufacturing, and/or test.

### DETAILED DESCRIPTION OF THE PREFERRED EMBODIMENTS

In accordance with features of the invention, a signal timing adjustment circuit is provided for setting the timing of critical signals in memory arrays properly across logic device and memory device process variation. The signal timing adjustment circuit adjusts timing of memory array sensitive signals to account for independent variation of logic devices and memory devices.

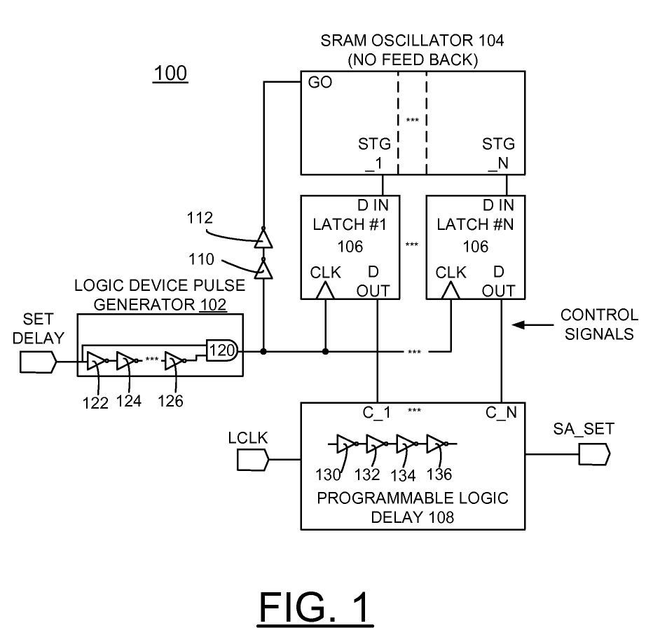

Having reference now to the drawings, in FIG. 1, there is shown a signal timing adjustment circuit generally designated by the reference character 100 in accordance with the preferred embodiment. Signal timing adjustment circuit 100 includes a Logic Device Pulse Generator 102, a static random access memory (SRAM) oscillator 104 formed of SRAM cells, a plurality of latches 106, #1-#N, each latch 106 coupled to a respective stage STG_1-STG_N of the SRAM oscillator 104, and a programmable logic delay 108.

The signal timing adjustment circuit 100 is used for properly setting the timing of critical signals in memory arrays across logic device and memory device process variation. The signal timing adjustment circuit 100 receives an input signal SET DELAY and provides an output SA_SET.

The Logic Device Pulse Generator 102 uses logic devices to create an output pulse responsive to the input signal SET DELAY. The width of the output pulse is dependent upon the delay through the logic devices. The output pulse width reflects logic device process variation. The pulse output of the Logic Device Pulse Generator 102 is applied via a pair of series connected inverters 110, 112 to the SRAM oscillator 104.

The SRAM oscillator 104 is a ring oscillator circuit having a series read and parallel restore operation, and configured with no feedback so that SRAM oscillator 104 does not oscillate. The delay through the SRAM oscillator 104 is determined by the SRAM cell performance of the SRAM cells forming the SRAM oscillator 104 responsive to the applied pulse output of the Logic Device Pulse Generator 102. The SRAM oscillator 104 includes the plurality of stages #1-N providing respective output signals STG_1-STG_N that after input GO transitions high, the signals STG_1 through STG_N sequentially go high. The time it takes for this ‘1’ to propagate through the signals STG_1 through STG_N is determined by the speed of the SRAM cell forming the SRAM oscillator 104. When the GO signal is low, the signals STG_1 through STG_N are reset in parallel back to ‘0’.

A respective example circuit for implementing the Logic Device Pulse Generator 102 and the Programmable Logic Delay 108 is shown in FIG. 1, while it should be understood that various other circuits could be used to implement the Logic Device Pulse Generator 102 and the Programmable Logic Delay 108.

As shown in FIG. 1, the input signal SET DELAY to the Logic Device Pulse Generator 102 is applied to an AND gate 120. A plurality of inverters 122, 124, 126 arranged in a string receiving the input signal SET DELAY and providing a delayed input to a second input of the AND gate 120. The output of AND gate is an output pulse having a width dependent upon the delay through the logic devices defining the AND gate 120 and inverters 122, 124, 126.

The illustrated Programmable Logic Delay 108 includes a plurality of inverters 130, 132, 134, 136 arranged in a string and defined by logic devices, generating a delay that is programmable via the control signals C_1 through C_N.

Operation of the signal timing adjustment circuit 100 may be further understood as follows: When the input signal SET DELAY transitions high, the Logic Device Pulse Generator 102 generates a pulse at its output. This output pulse width is dependent upon the delay of the logic devices, which are used to form the Logic Device Pulse Generator 102. If logic devices speed up due to process variation, the pulse width will be smaller. If logic devices slow down due to process variation, the pulse width will be wider.

While the output pulse applied to input GO of SRAM oscillator 104 is high, the latches 106 become transparent and the SRAM Oscillator 104 (having no feedback so it does not oscillate) begins to propagate a ‘1’ on STG_1 through STG_N. The speed at which the ‘1’s are propagated on STG_1 through STG_N is determined by the speed of the SRAM cells. If the SRAM cells speed up, the propagation will happen faster. If the SRAM cells slow down the propagation will happen slower.

When the output pulse applied to input GO of SRAM oscillator 104 goes low, the number of STG_X signals that went high is captured in the latches 106. Also, after a small delay shown by the inverters 110, 112, the input GO signal controlling the SRAM Oscillator 104 goes low causing the signals STG_1 through STG_N to be reset back to ‘0’. The delay through inverters 110, 112 is adjusted to guard against STG_1 through STG_N precharged values flushing into the latches 106.

Now, there are ‘1’s stored in the first portion of the latches 106 and ‘0’s stored in the last portion of the latches 106. The amount of logic delay in the Logic Pulse Generator 102 and the number of stages of the SRAM Oscillator 104 is chosen such that under nominal process conditions half of the latches capture a ‘1’.

The data stored in the latches 106 at latch output D OUT are connected to control the Programmable Logic Delay 108. These control signals are connected or decoded within the Programmable Logic Delay 108 such that more l's stored in the latches 106 means that the Programmable Logic Delay 108 is programmed for less delay. This is because if more than half of the latches store ‘1’s, then the logic devices must be slow relative to the SRAM devices. Also, if less than half of the latches store ‘1’s, the Programmable Logic Delay 102 is programmed for more delay. This is because if less than half of the latches store ‘1’s, the logic devices are fast relative to the SRAM devices. Each possible number of ‘1’s in the latches 106 maps to a different amount of delay provided by the Programmable Logic Delay 108.

The output of the Programmable Logic Delay 108 is labeled SASET and could be used to selectively control sense amplifiers, wordline pulse widths, and global precharge signals. Also, the control signals C_1 through C_N can be connected to a Programmable Logic Delay that is built into one memory macro or many memory macros.

In summary, the signal timing adjustment circuit 100 measures the relative performance of logic devices and SRAM cells and adjusts the critical signal timing of memory arrays or macros accordingly.

It should be understood that the present invention is not limited to the illustrated signal timing adjustment circuit 100. For example, various different circuits can be provided to implement the Programmable Logic Delay 102, SRAM oscillator 104, latches 106, and the Programmable Logic Delay 108. Also protection against a defect in the SRAM Oscillator can be provided. For example, replacing the latches 106 with scannable latches can provide this Then, if it is determined that there is a defect in the SRAM Oscillator 104, a nominal value would be scanned into the latches to set the Programmable Logic Delay to a nominal delay value. Then, all circuits dependant on this signal timing adjustment circuit 100 could still operate as normal.

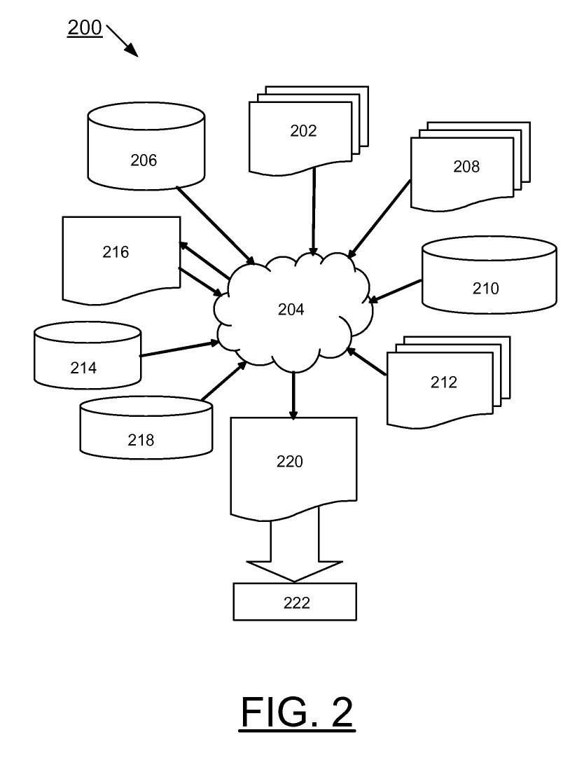

FIG. 2 shows a block diagram of an example design flow 200. Design flow 200 may vary depending on the type of IC being designed. For example, a design flow 200 for building an application specific IC (ASIC) may differ from a design flow 200 for designing a standard component. Design structure 202 is preferably an input to a design process 204 and may come from an IP provider, a core developer, or other design company or may be generated by the operator of the design flow, or from other sources. Design structure 202 comprises circuit 100 in the form of schematics or HDL, a hardware-description language, for example, Verilog, VHDL, C, and the like. Design structure 202 may be contained on one or more machine readable medium. For example, design structure 202 may be a text file or a graphical representation of circuit 100. Design process 204 preferably synthesizes, or translates, circuit 100 into a netlist 206, where netlist 206 is, for example, a list of wires, transistors, logic gates, control circuits, I/O, models, etc. that describes the connections to other elements and circuits in an integrated circuit design and recorded on at least one of machine readable medium. This may be an iterative process in which netlist 206 is resynthesized one or more times depending on design specifications and parameters for the circuit.

Design process 204 may include using a variety of inputs; for example, inputs from library elements 208 which may house a set of commonly used elements, circuits, and devices, including models, layouts, and symbolic representations, for a given manufacturing technology, such as different technology nodes, 32 nm, 45 nm, 90 nm, and the like, design specifications 210, characterization data 212, verification data 214, design rules 216, and test data files 218, which may include test patterns and other testing information. Design process 204 may further include, for example, standard circuit design processes such as timing analysis, verification, design rule checking, place and route operations, and the like. One of ordinary skill in the art of integrated circuit design can appreciate the extent of possible electronic design automation tools and applications used in design process 204 without deviating from the scope and spirit of the invention. The design structure of the invention is not limited to any specific design flow.

Design process 204 preferably translates an embodiment of the invention as shown in FIG. 1 along with any additional integrated circuit design or data (if applicable), into a second design structure 220. Design structure 220 resides on a storage medium in a data format used for the exchange of layout data of integrated circuits, for example, information stored in a GDSII (GDS2), GL1, OASIS, or any other suitable format for storing such design structures. Design structure 220 may comprise information such as, for example, test data files, design content files, manufacturing data, layout parameters, wires, levels of metal, vias, shapes, data for routing through the manufacturing line, and any other data required by a semiconductor manufacturer to produce an embodiment of the invention as shown in FIG. 1. Design structure 220 may then proceed to a stage 222 where, for example, design structure 220 proceeds to tape-out, is released to manufacturing, is released to a mask house, is sent to another design house, is sent back to the customer, and the like.

While the present invention has been described with reference to the details of the embodiments of the invention shown in the drawing, these details are not intended to limit the scope of the invention as claimed in the appended claims.

What is claimed is:

1. A signal timing adjustment circuit for implementing variation tolerant memory array signal timing comprising:
a set delay signal;
a logic circuit formed of logic devices, said logic circuit receiving the set delay signal and generating a first delay signal based upon logic devices forming the logic circuit;
a memory cell circuit formed of memory cell devices, said memory cell circuit receiving the first delay signal and generating control signals responsive to the first delay signal and based upon memory cell devices forming the memory cell circuit; and
a programmable logic delay circuit coupled to said memory cell circuit, said programmable logic delay circuit receiving the control signals and generating a timing adjustment signal.

2. The signal timing adjustment circuit as recited in claim 1, wherein said logic circuit generating the first delay signal includes a logic device pulse generator.

3. The signal timing adjustment circuit as recited in claim 2, wherein said logic device pulse generator generates an output pulse having a width dependent upon a delay of the logic devices forming the logic circuit pulse generator.

4. The signal timing adjustment circuit as recited in claim 1, wherein said memory cell circuit includes a static random access memory (SRAM) oscillator.

5. The signal timing adjustment circuit as recited in claim 4, further includes a plurality of latches connected to the SRAM oscillator.

6. The signal timing adjustment circuit as recited in claim 5, wherein a respective latch of said plurality of latches is coupled to each respective stage of said SRAM oscillator.

7. The signal timing adjustment circuit as recited in claim 6, wherein an output of said latches provides the control signals responsive to the first delay signal and based upon memory cell devices forming the memory cell circuit.

8. The signal timing adjustment circuit as recited in claim 1, wherein said programmable logic delay circuit is formed of a plurality of logic devices, said plurality of logic devices are programmable by the control signals.

9. A signal timing adjustment method for implementing variation tolerant memory array signal timing comprising:
providing a set delay signal;
providing a logic circuit formed of logic devices, applying the set delay signal to said logic circuit and generating a first delay signal based upon logic devices forming the logic circuit;
providing a memory cell circuit formed of memory cell devices, applying the first delay signal to said memory cell circuit and generating control signals responsive to the first delay signal and based upon memory cell devices forming the memory cell circuit; and
providing a programmable logic delay circuit coupled to said memory cell circuit, applying the control signals to said programmable logic delay circuit and generating a timing adjustment signal.

10. The signal timing adjustment method as recited in claim 9, wherein providing a logic circuit formed of logic devices includes providing a logic circuit pulse generator.

11. The signal timing adjustment method as recited in claim 10, wherein generating a first delay signal based upon logic devices forming the logic circuit includes generating an output pulse having a width dependent upon a delay of the logic devices forming said logic circuit pulse generator.

12. The signal timing adjustment method as recited in claim 9, wherein providing a memory cell circuit formed of memory cell devices includes providing a static random access memory (SRAM) oscillator and a plurality of latches connected to the SRAM oscillator.

13. The signal timing adjustment method as recited in claim 12, wherein a respective latch of said plurality of latches is coupled to each respective stage of said SRAM oscillator, and providing an output of said latches for generating the control signals responsive to the first delay signal and based upon memory cell devices forming the memory cell circuit.

14. The signal timing adjustment method as recited in claim 9, wherein providing said programmable logic delay circuit includes forming said programmable logic delay circuit of a plurality of logic devices, and programming said plurality of logic devices by the control signals.

15. A design structure tangibly embodied in a machine readable medium used in a design process, the design structure comprising:
a signal timing adjustment circuit tangibly embodied in the machine readable medium used in the design process, said signal timing adjustment circuit implementing variation tolerant memory array signal timing and said signal timing adjustment circuit including a set delay signal;
a logic circuit formed of logic devices, said logic circuit receiving the set delay signal and generating a first delay signal based upon logic devices forming the logic circuit;
a memory cell circuit formed of memory cell devices, said memory cell circuit receiving the first delay signal and generating control signals responsive to the first delay signal and based upon memory cell devices forming the memory cell circuit; and
a programmable logic delay circuit coupled to said memory cell circuit, said programmable logic delay circuit receiving the control signals and generating a timing adjustment signal, wherein the design structure, when read and used in the manufacture of a semiconductor chip produces a chip comprising said signal timing adjustment circuit.

16. The design structure of claim 15, wherein the design structure comprises a netlist, which describes said signal timing adjustment circuit.

17. The design structure of claim 15, wherein the design structure resides on storage medium as a data format used for the exchange of layout data of integrated circuits.

18. The design structure of claim 15, wherein the design structure includes at least one of test data files, characterization data, verification data, or design specifications.

19. The design structure of claim 15, wherein said logic circuit generating the first delay signal includes a logic device pulse generator, and said logic device pulse generator generates an output pulse having a width dependent upon a delay of the logic devices forming the logic circuit pulse generator.

20. The design structure of claim 15, wherein said memory cell circuit includes a static random access memory (SRAM) oscillator and a plurality of latches connected to the SRAM oscillator; and a respective latch of said plurality of latches is coupled to each respective stage of said SRAM oscillator, and an output of said latches generating the control signals responsive to the first delay signal and based upon memory cell devices forming the memory cell circuit.
